(19) United States
(12) Patent Application Publication
(10) Pub. No.: US 2026/0177637 A1
(43) Pub. Date: Jun. 25, 2026

(54) DIAGNOSIS SYSTEM FOR POWER SUPPLY DISTRIBUTION CIRCUIT

(71) Applicant: TOYOTA JIDOSHA KABUSHIKI KAISHA, Toyota-shi (JP)

(72) Inventors: Masayuki SUZUKI, Toyota-shi (JP); Satoru TAKEMOTO, Okazaki-shi (JP)

(73) Assignee: TOYOTA JIDOSHA KABUSHIKI KAISHA, Toyota-shi (JP)

(21) Appl. No.: 19/401,076

(22) Filed: Nov. 25, 2025

(30) Foreign Application Priority Data
Dec. 25, 2024 (JP) 2024-229143

(51) Int. Cl. G01R 31/40; B60L 58/12; G01R 31/00; G07C 5/08; H01M 10/42

(52) U.S. Cl. CPC G01R 31/40; G01R 31/006; H01M 10/4285; B60L 58/12; B60L 2210/10; B60L 2240/547; B60L 2240/549; G07C 5/0808; H01M 2220/20

(57) ABSTRACT

A system for diagnosing a power supply distribution circuit that distributes power supplied from a DC-DC converter and an auxiliary battery to a plurality of loads, the system comprising: a plurality of switches provided between the DC-DC converter and the auxiliary battery and the loads; a switching unit that switches a connection state of the switches; and a diagnosis unit that diagnoses the power supply distribution circuit based on the connection state of the switches and a change in voltage and current in the power supply distribution circuit.

### CROSS-REFERENCE TO RELATED APPLICATION

This application claims priority to Japanese Patent Application No. 2024-229143 filed on Dec. 25, 2024. The disclosure of the above-identified application, including the specification, drawings, and claims, is incorporated by reference herein in its entirety.

### BACKGROUND

### 1. Technical Field

The present disclosure relates to a system for diagnosing a power supply distribution circuit that distributes power supplied from a DC-DC converter and an auxiliary battery to a plurality of loads.

### 2. Description of Related Art

Japanese Patent No. 6306185 (JP 6306185 B) discloses a method of detecting a disconnection of a battery in a system on which electric circuits connected to each other by a DC-DC converter are mounted. In the method disclosed in JP 6306185 B, determination is made that a circuit network is normal by detecting a charge and discharge current of the battery by intentionally raising and lowering an output voltage of the DC-DC converter using a periodic control signal generated by an oscillation circuit.

### SUMMARY

In the system disclosed in JP 6306185 B, the circuit network to which the DC-DC converter and the battery are connected is diagnosed. In this case, there is a problem that an additional configuration for controlling the output voltage of the DC-DC converter is required in addition to the existing configuration.

The present disclosure has been made in view of the above problem, and an object thereof is to provide a diagnosis system for a power supply distribution circuit that can diagnose a circuit network by using a configuration that is already provided, without requiring any additional configuration.

In order to solve the above problem, an aspect of the present disclosed technology is
a diagnosis system for a power supply distribution circuit,
the diagnosis system being a system of diagnosing the power supply distribution circuit that distributes power supplied from a DC-DC converter and an auxiliary battery to a plurality of loads, the diagnosis system including:
a plurality of switches provided between the DC-DC converter and the auxiliary battery on one side and the loads on another side;
a switching unit configured to switch connection states of the switches; and
a diagnosis unit configured to diagnose the power supply distribution circuit based on the connection states of the switches and changes in a voltage and a current in the power supply distribution circuit.

With the diagnosis system for a power supply distribution circuit according to the present disclosure, the power supply distribution circuit to which the DC-DC converter and the auxiliary battery are connected can be diagnosed by using a configuration that is already provided, without requiring any additional configuration.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a diagnosis system for a power supply distribution circuit according to an embodiment of the present disclosure;

FIG. 2A is a processing flowchart of circuit diagnosis control executed by the diagnosis system for a power supply distribution circuit; and

FIG. 2B is a processing flowchart of circuit diagnosis control executed by the diagnosis system for a power supply distribution circuit.

### DETAILED DESCRIPTION OF EMBODIMENTS

The diagnosis system for a power supply distribution circuit of the present disclosure uses an existing sensor provided for auxiliary battery control and a relay of the power supply distribution circuit. As a result, the normality/abnormality of the power supply distribution circuit is diagnosed without using a method of intentionally lowering the output voltage of the DC-DC converter from the control signal as in the related art. Hereinafter, an embodiment of the present disclosure will be described in detail with reference to the drawings.

### EMBODIMENT

### Configuration

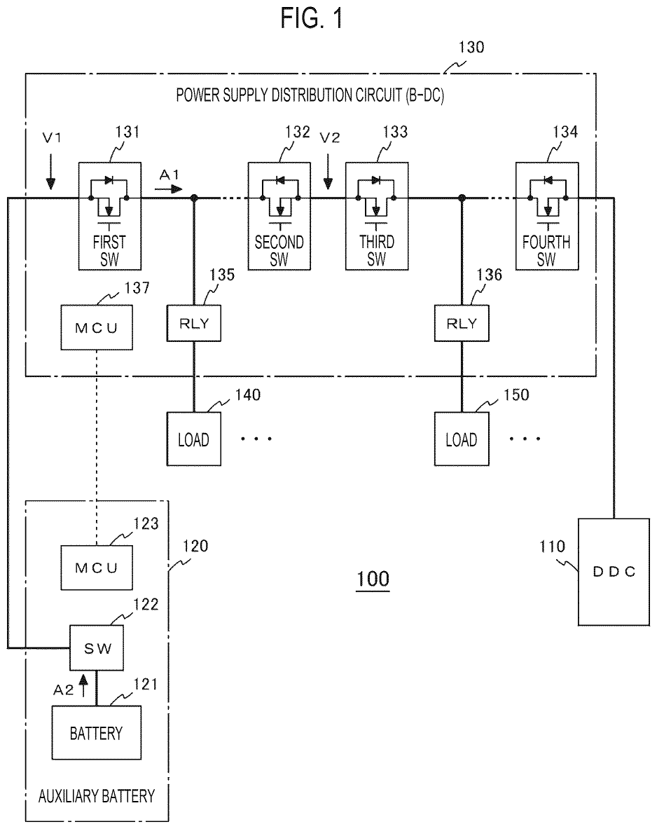

FIG. 1 is a schematic configuration diagram illustrating a diagnosis system 100 for a power supply distribution circuit according to an embodiment of the present disclosure. The diagnosis system 100 for a power supply distribution circuit illustrated in FIG. 1 comprises a DC-DC converter (DDC) 110, an auxiliary battery 120, a power supply distribution circuit (B-DC) 130, and a plurality of loads 140 to 150. In FIG. 1, a power line through which power is exchanged is indicated by a solid line, and a control signal line through which a request, an instruction, or the like is exchanged is indicated by a broken line.

The diagnosis system 100 for a power supply distribution circuit illustrated in FIG. 1 is mounted on a vehicle as an example, such as a hybrid electric vehicle (HEV), a plug-in hybrid electric vehicle (PHEV), and a battery electric vehicle (BEV).

The DC-DC converter (DDC) 110 is a power supply source that supplies power to the power supply distribution circuit 130. More specifically, the DC-DC converter 110 is a power converter that converts a voltage of power input from a high-voltage battery (not illustrated) into a voltage required by the loads 140 to 150 and outputs the converted voltage to the power supply distribution circuit 130.

The auxiliary battery 120 is a secondary battery configured to be chargeable and dischargeable, such as a lithium ion battery. The auxiliary battery 120 is a power supply source that can supply power stored therein to the power supply distribution circuit 130. The auxiliary battery 120 includes a battery 121, a switch (SW) 122, and an MCU 123.

The battery 121 is configured as, for example, a battery pack in which lithium ion battery cells are connected in series. The switch (SW) 122 is a switch element that can switch an electrical connection state between the battery 121 and the power supply distribution circuit 130. A semiconductor relay or the like is used as the switch 122. The MCU 123 is a control unit configured by, for example, a microcomputer, and can acquire a state (voltage, current, and the like) of the battery 121 via a sensor (not illustrated), control a connection state of the switch 122, or the like. The MCU 123 is communicably connected to an MCU 137 of the power supply distribution circuit 130 (described below) via a network such as CAN.

The power supply distribution circuit (B-DC) 130 uses the DC-DC converter (DDC) 110 and the auxiliary battery 120 as a power supply source. The power supply distribution circuit (B-DC) 130 is a control unit (bode domain controller) for controlling power supply to a plurality of loads 140 to 150 from the power supply reduction. The power supply distribution circuit 130 includes a first switch (first SW) 131, a second switch (second SW) 132, a third switch (third SW) 133, and a fourth switch (fourth SW) 134. In addition, the power supply distribution circuit 130 includes a plurality of relays (RLY) 135, 136 and the MCU 137.

The first switch (first SW) 131 is a switch element for switching a power supply state from the auxiliary battery 120 to the power supply distribution circuit (B-DC) 130. The fourth switch (fourth SW) 134 is a switch element for switching a power supply state from the DC-DC converter (DDC) 110 to the power supply distribution circuit (B-DC) 130. The second switch (second SW) 132 and the third switch (third SW) 133 are switch elements provided in a series configuration in which rectifying directions of the parasitic diodes are reversed between the first switch 131 and the fourth switch 134. The relays (RLY) 135, 136 are switch elements for respectively switching a power supply state to the load 140 and the load 150. A semiconductor relay or the like is used for the first switch 131, the second switch 132, the third switch 133, the fourth switch 134, and the relays 135, 136. The MCU 137 is a control unit configured by, for example, a microcontroller. The MCU 137 can acquire a voltage or a current at a predetermined location in the power supply distribution circuit 130 via a sensor (not shown). In addition, the MCU 137 can control connection states of the first switch 131, the second switch 132, the third switch 133, and the fourth switch 134. In addition, the MCU 137 diagnoses the power supply distribution circuit 130 based on a voltage, a current, or the like at a predetermined location in the power supply distribution circuit 130. The MCU 137 is communicably connected to the MCU 123 of the auxiliary battery 120 via a network such as CAN.

The loads 140, 150 are vehicle-mounted loads that consume electric power by driving electronic control units (ECUs) or actuators (ACTs) mounted on the vehicle. The loads 140, 150 are operated by electric power supplied from the DC-DC converter 110 and/or electric power supplied from the auxiliary battery 120.

The number of the relays (RLY) 135, 136 and the number of the loads 140, 150 mounted on the vehicle are not limited to the numbers shown in FIG. 1.

### Control

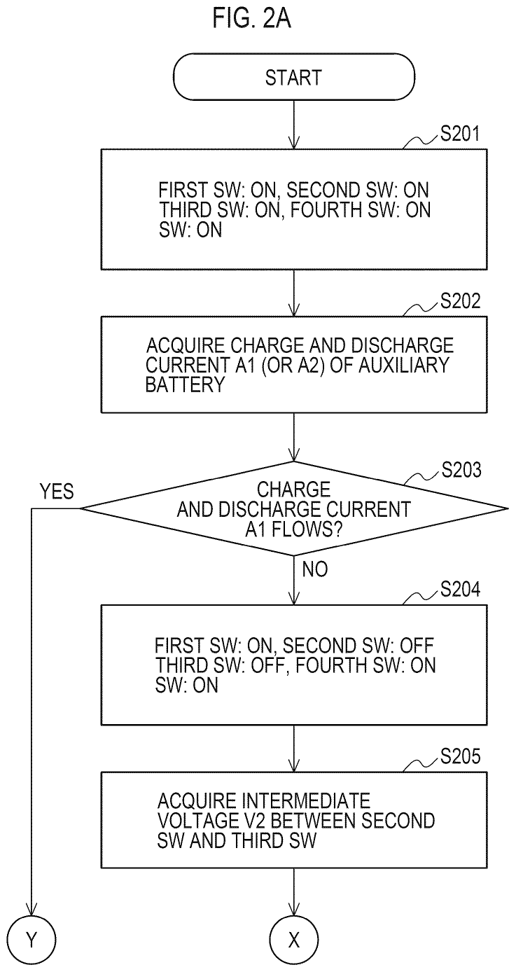

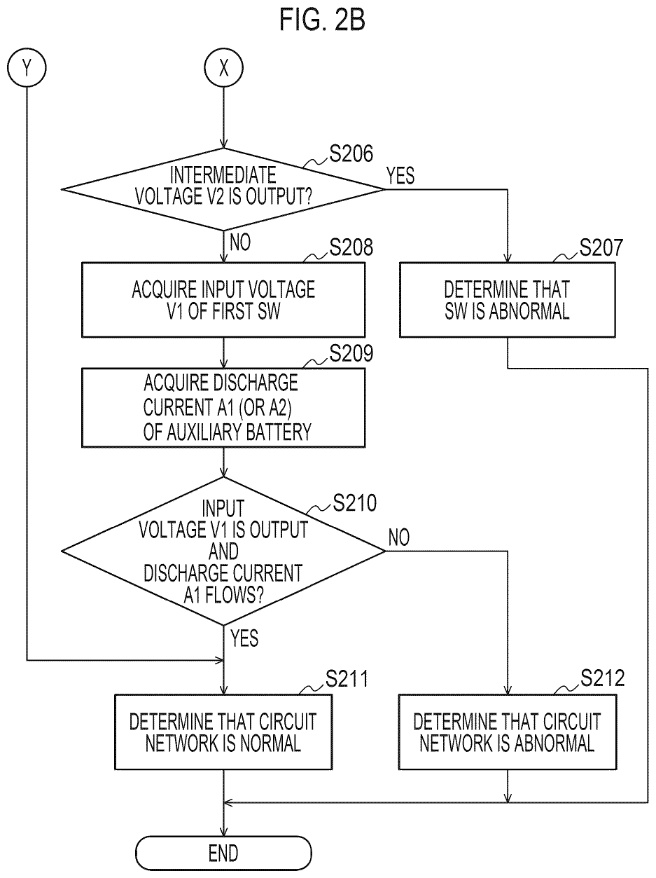

Next, the control performed in the diagnosis system 100 of the power supply distribution circuit according to the present embodiment will be described with further reference to FIGS. 2A and 2B. FIGS. 2A and 2B are flowcharts for describing a processing procedure of circuit diagnosis control executed by the MCU 137 of the power supply distribution circuit 130 and the MCU 123 of the auxiliary battery 120. The processing of FIG. 2A and the processing of FIG. 2B are coupled by the couplers X and Y, respectively. The circuit diagnosis control illustrated in FIGS. 2A and 2B is started, for example, in a state where the safety of the vehicle is ensured, such as while the vehicle is parked.

### S201

The MCU 137 of the power supply distribution circuit 130 controls the first switch (first SW) 131, the second switch (second SW) 132, the third switch (third SW) 133, and the fourth switch (fourth SW) 134 to be in the conduction state (ON) (switching unit). In addition, the MCU 123 of the auxiliary battery 120 controls the switch (SW) 122 to be in the conduction state. In a case where each of the switches is controlled to be in the conduction state, the processing proceeds to S202.

### S202

The MCU 137 of the power supply distribution circuit 130 acquires a current A1 flowing through the first switch (first SW) 131 as information on the charge and discharge current of the auxiliary battery 120. It should be noted that a battery 121 current A2 flowing into and out of the auxiliary battery 120 may be used as the information on the charge and discharge current of the auxiliary battery 120. In a case where the charge and discharge current A1 (or A2) is acquired, the processing proceeds to S203.

### S203

The MCU 137 of the power supply distribution circuit 130 determines whether the charge and discharge current A1 flows through the auxiliary battery 120. This determination is performed to check whether the auxiliary battery 120 and the power supply distribution circuit 130 are normally connected. The presence or absence of the charge and discharge current A1 may be determined not only by whether the current is zero but also by whether the current exceeds a predetermined value. In a case where determination made that the charge and discharge current A1 flows (S203, Yes), the processing proceeds to S211. On the other hand, in a case where determination made that the charge and discharge current A1 does not flow (S203, No), the processing proceeds to S204.

### S204

The MCU 137 of the power supply distribution circuit 130 controls the first switch (first SW) 131 and the fourth switch (fourth SW) 134 to be in the conductive state (ON). Further, the MCU 137 controls the second switch (second SW) 132 and the third switch (third SW) 133 to be in the cutoff state (OFF) (switching unit). In addition, the MCU 123 of the auxiliary battery 120 controls the switch (SW) 122 to be in the conduction state. In a case where each of the switches is controlled to be in the conductive state or the cutoff state, the processing proceeds to S205.

### S205

The MCU 137 of the power supply distribution circuit 130 acquires the intermediate voltage V2 between the second switch (second SW) 132 and the third switch (third SW) 133. In a case where the intermediate voltage V2 is acquired, the processing proceeds to S206.

### S206

The MCU 137 of the power supply distribution circuit 130 determines whether the intermediate voltage V2 between the second switch (second SW) 132 and the third switch (third SW) 133 is output. This determination is performed to check whether the second switch 132 and/or the third switch 133 is operating normally. In a case where determination made that the intermediate voltage V2 is output (S206, Yes), the processing proceeds to S207. On the other hand, in a case where determination made that the intermediate voltage V2 is not output (S206, No), the processing proceeds to S208.

### S207

The MCU 137 of the power supply distribution circuit 130 determines that at least one of the second switch (second SW) 132 or the third switch (third SW) 133 is abnormal (ON sticking) (diagnosis unit). It is possible to determine which switch is abnormal based on the value of the intermediate voltage V2 (the value of the auxiliary battery 120 or the value of the DC-DC converter 110). In a case where determination made that at least one of the second switch 132 or the third switch 133 is abnormal, the present circuit diagnosis control ends.

### S208

The MCU 137 of the power supply distribution circuit 130 acquires a voltage V1 appearing at an input terminal of the first switch (first SW) 131 as information on the output voltage of the auxiliary battery 120. In a case where the input voltage V1 is acquired, the processing proceeds to S209.

### S209

The MCU 137 of the power supply distribution circuit 130 acquires a current A1 flowing through the first switch (first SW) 131 as information on the discharge current of the auxiliary battery 120. It should be noted that a battery 121 outflow current A2 in the auxiliary battery 120 may be used as the information on the discharge current of the auxiliary battery 120. In a case where the discharge current A1 is acquired, the processing proceeds to S210.

### S210

The MCU 137 of the power supply distribution circuit 130 determines whether the input voltage V1 of the first switch (first SW) 131 is output and the discharge current A1 flows from the auxiliary battery 120. This determination is performed to check whether the auxiliary battery 120 and the power supply distribution circuit 130 are normally connected. The presence or absence of the input voltage V1 may be determined not only by whether the voltage is zero, but also by whether the voltage exceeds a predetermined value. In addition, the presence or absence of the discharge current A1 may be determined not only by whether the current is zero, but also by whether the current exceeds a predetermined value. In a case where determination made that the input voltage V1 is output and the discharge current A1 flows (S210, Yes), the processing proceeds to S211. On the other hand, in a case where the other determination is made (S210, No), the processing proceeds to S212.

### S211

The MCU 137 of the power supply distribution circuit 130 determines that the circuit network of the power supply distribution circuit 130 is normal (diagnosis unit). Specifically, determination made that the wiring system (the wiring harness, the first switch (first SW) 131, or the like) on the battery side that electrically connects the auxiliary battery 120 and the power supply distribution circuit 130 is normal. In a case where determination made that the circuit network of the power supply distribution circuit 130 is normal, the circuit diagnosis control ends.

### S212

The MCU 137 of the power supply distribution circuit 130 determines that the circuit network of the power supply distribution circuit 130 is abnormal (diagnosis unit). Specifically, determination made that the wiring system (the wiring harness, the first switch (first SW) 131, or the like) on the battery side that electrically connects the auxiliary battery 120 and the power supply distribution circuit 130 is abnormal. In a case where determination made that the circuit network of the power supply distribution circuit 130 is abnormal, the circuit diagnosis control ends.

### Action and Effect

As described above, the diagnosis system 100 of the power supply distribution circuit according to the embodiment of the present disclosure appropriately switches and controls the first switches (SW) 131 to the fourth switch 134. The first switch 131 to the fourth switch 134 are provided between the DC-DC converter 110 and the auxiliary battery 120 and the loads 140 to 150. Then, the normality/abnormality of the power supply distribution circuit 130 is diagnosed based on the connection states of the first switches 131 to the fourth switch 134 and the changes in the voltage and the current in the power supply distribution circuit 130.

With this circuit diagnosis control, the power supply distribution circuit 130 to which the DC-DC converter 110 and the auxiliary battery 120 are connected can be diagnosed by using only the already provided configuration.

The embodiment of the present disclosure has been described above. However, the present disclosure is not limited to the diagnosis system for the power supply distribution circuit described above. The present disclosure can be regarded as a method executed by a diagnosis system for a power supply distribution circuit including a processor and a memory, and as a program of the method. In addition, the present disclosure can be regarded as a computer-readable non-transitory recording medium storing the program, a vehicle equipped with the diagnosis system for the power supply distribution circuit, or the like.

The diagnosis system for a power supply distribution circuit of the present disclosure can be used in a vehicle including a DC-DC converter and an auxiliary battery.

What is claimed is:

1. A diagnosis system for a power supply distribution circuit, the diagnosis system being a system of diagnosing the power supply distribution circuit that distributes power supplied from a DC-DC converter and an auxiliary battery to a plurality of loads, the diagnosis system comprising:
a plurality of switches provided between the DC-DC converter and the auxiliary battery on one side and the loads on another side;
a switching unit configured to switch connection states of the switches; and
a diagnosis unit configured to diagnose the power supply distribution circuit based on the connection states of the switches and changes in a voltage and a current in the power supply distribution circuit.

2. The diagnosis system according to claim 1, wherein the diagnosis unit is configured to diagnose the power supply distribution circuit based on whether a charge and discharge current is present between the auxiliary battery and the power supply distribution circuit in a state in which the DC-DC converter is connected to the power supply distribution circuit.

3. The diagnosis system according to claim 1, wherein the diagnosis unit is configured to diagnose the power supply distribution circuit based on whether a voltage and a current are present between the auxiliary battery and the power supply distribution circuit in a state in which the DC-DC converter is disconnected from the power supply distribution circuit.
